(19) United States
(12) Patent Application Publication
(10) Pub. No.: US 2015/0114699 A1
(43) Pub. Date: Apr. 30, 2015

(54) INSULATION MATERIAL, PRINTED CIRCUIT BOARD USING THE SAME AND METHOD OF MANUFACTURING THE SAME

(71) Applicant: SAMSUNG ELECTRO-MECHANICS CO., LTD., Suwon-Si (KR)

(72) Inventors: Young Gwan Ko, Suwon-si (KR); Yong Jin Park, Suwon-si (KR); Kang Wook Bong, Suwon-Si (KR); Hye Won Jung, Suwon-Si (KR); Young Kuk Ko, Suwon-Si (KR); Joon Sung Kim, Suwon-Si (KR)

(73) Assignee: SAMSUNG ELECTRO-MECHANICS CO., LTD., Suwon-Si (KR)

(21) Appl. No.: 14/444,964

(22) Filed: Jul. 28, 2014

(30) Foreign Application Priority Data
Oct. 24, 2013 (KR) 10-2013-0127190

(51) Int. Cl. H05K 1/03; H05K 1/11; H05K 3/40

(52) U.S. Cl. CPC H05K 1/0306; H05K 3/4038; H05K 1/038; H05K 1/115; H05K 2201/2009
USPC 174/258; 428/195.1; 428/196; 29/852; 174/262

(57) ABSTRACT

There are provided an insulation material, a printed circuit board using the same, and a method of manufacturing the same. The insulation material includes a via region in which a via is to be formed; and a reinforcement material, wherein the via region and the reinforcement material are formed to be spaced apart from each other.

### CROSS-REFERENCE TO RELATED APPLICATION

This application claims the foreign priority benefit of Korean Patent Application No. 10-2013-0127190, filed on Oct. 24, 2013, entitled “Insulation Materials, Printed Circuit Board and the Method of Manufacturing the Same” which is hereby incorporated by reference in its entirety into this application.

### BACKGROUND

Embodiments of the present disclosure relates to an insulation material, a printed circuit board using the same, and a method of manufacturing the same.

High integration of electronic components according to miniaturization of an electronic device has been rapidly conducted. This trend has also required various changes for a printed circuit board (PCB). In accordance with trends into fineness of a line/space and a chip connection pad interval and mobilization, thinness has been performed and high multi-layer according to high integration has been required, thereby sharply increasing manufacturing costs. In addition, demand intended to conduct a through hole of a core layer and a blind via hole of a build-up layer with fill plating has been increased. In this case, in order to smoothly perform the fill plating within the hole, a structure within the hole allowing a plating solution to be actively circulated is essential.

### RELATED ART DOCUMENT

### Patent Document

(Patent Document 1) Korean Patent Laid-Open Publication No. 2011-0122811

### SUMMARY

An aspect of the present disclosure may provide an insulation material capable of increasing reliability by fabricating a weaving interval of glass cloth impregnated in the insulation material to correspond to a via region, a printed circuit board using the same, and a method of manufacturing the same.

According to an aspect of the present disclosure, an insulation material may include: a via region in which a via is to be formed; and a reinforcement material, wherein the via region and the reinforcement material are formed to be spaced apart from each other.

The reinforcement material may be glass cloth.

According to another aspect of the present disclosure, a printed circuit board may include: an insulation layer having a via region and a reinforcement material formed to be spaced apart from each other; circuit layers formed on the insulation layer; and a via electrically connected to the circuit layers.

The reinforcement material may be glass cloth.

The via region may have a diameter larger than that of the via.

The via may have a sandglass, taper shape or cylinder shape.

According to another aspect of the present disclosure, a method of manufacturing a printed circuit board may include: preparing a core substrate including an insulation layer having a via region and a reinforcement material formed to be spaced apart from each other; and forming a via within the via region to penetrate through the insulation layer in the core substrate.

The reinforcement material may be glass cloth.

The via region may have a diameter larger than that of the via.

The via may have a sandglass, taper shape or cylinder shape.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of an insulation material according to an exemplary embodiment of the present disclosure;

FIG. 2 is a plan view of the insulation material according to an exemplary embodiment of the present disclosure;

FIGS. 3 and 4 are cross-sectional views of a printed circuit board according to another exemplary embodiment of the present disclosure; and

FIGS. 5 through 7 are process flow charts of a method of manufacturing a printed circuit board according to still another exemplary embodiment of the present disclosure.

### DESCRIPTION OF EMBODIMENTS

The aspects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### Insulation Material

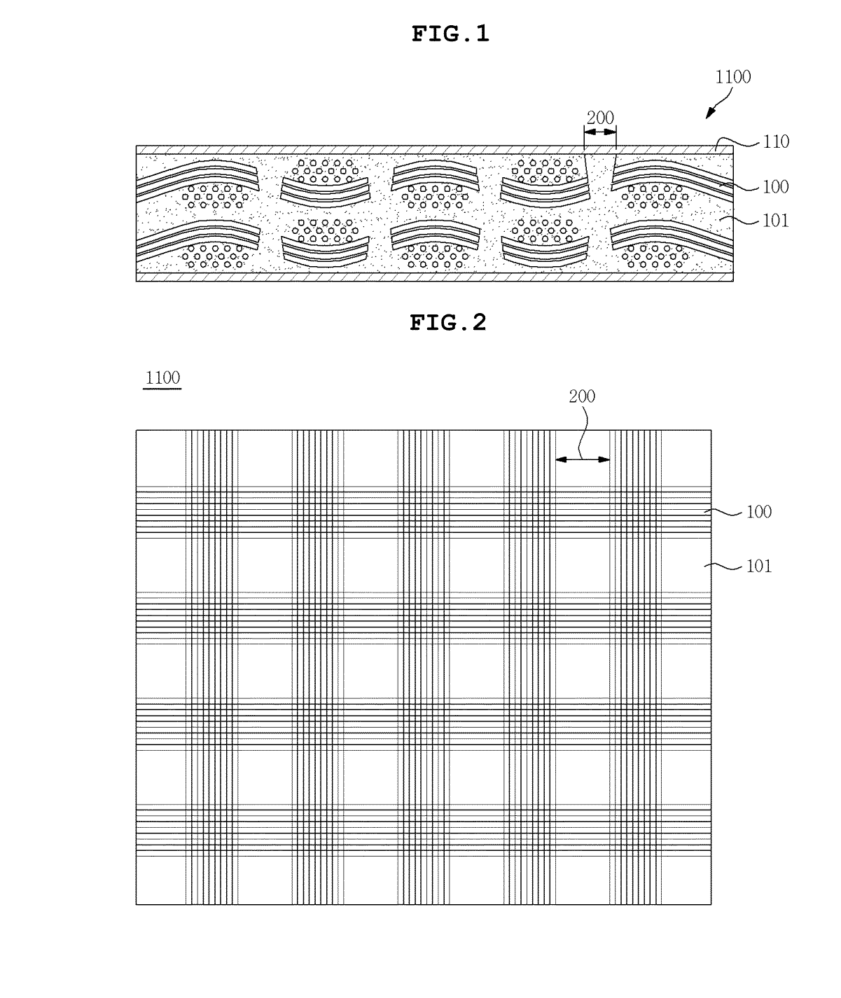

FIG. 1 is a cross-sectional view of an insulation material 1100 according to an exemplary embodiment of the present disclosure.

As shown in FIG. 1, the insulation material 1100 may include a via region 200 in which a via is to be formed, and a reinforcement material 100, and the via region 200 and the reinforcement material 100 are formed to be spaced apart from each other. Here, a via (not shown) may be further formed on the via region 200.

The reinforcement material 100 may be glass cloth.

The insulation material 1100 may have a structure in which the reinforcement material 100 is impregnated in a resin 101.

Here, the resin 101 may be a thermosetting resin such as an epoxy resin or a thermoplastic resin such as polyimide. Alternatively, the thermosetting resin, a photocurable resin, and the like may be used.

FIG. 2 is a plan view of the insulation material 1100 according to an exemplary embodiment of the present disclosure.

As shown in FIG. 2, the reinforcement material 100 may be glass cloth.

In addition, the reinforcement material 100 may be formed of glass cloth extended in a horizontal direction of a paper and glass cloth extended in a vertical direction of a paper.

In this case, the reinforcement material 100 may be formed in the remaining portions except for the via region 200.

### Printed Circuit Board

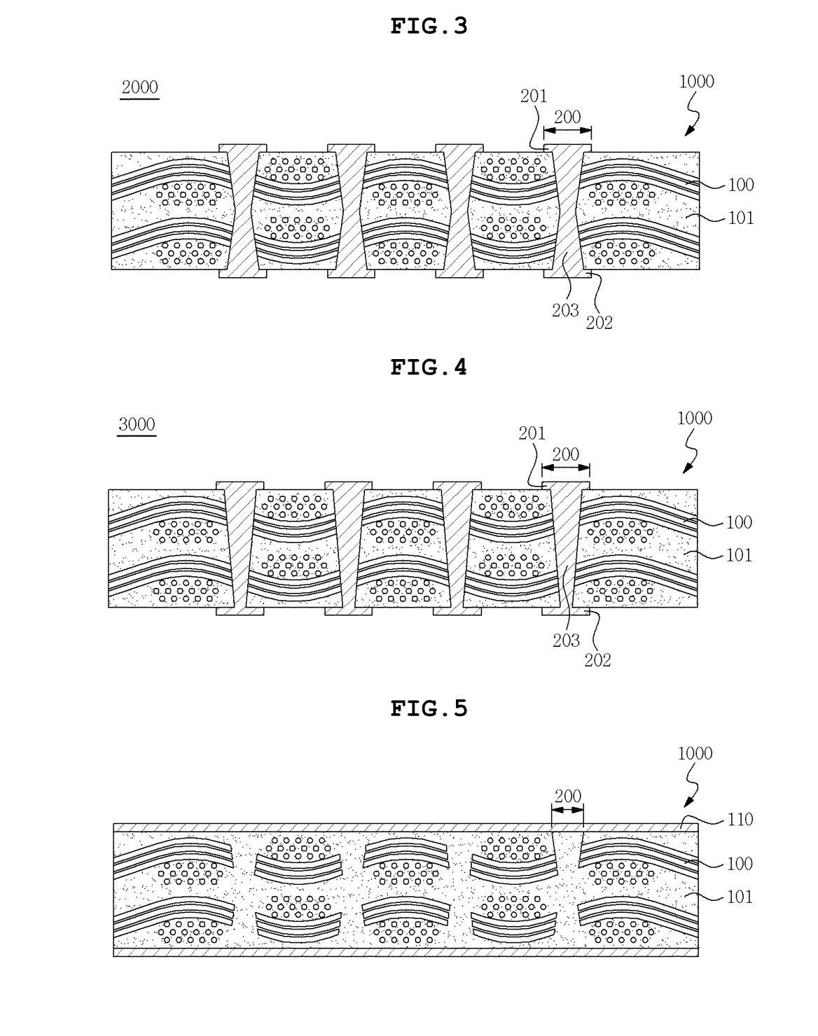

FIGS. 3 and 4 are cross-sectional views of a printed circuit board according to another exemplary embodiment of the present disclosure.

FIG. 3 is a cross-sectional view showing a core substrate.

As shown in FIG. 3, the printed circuit board 2000 may include an insulation layer 1000 having the via region 200 and the reinforcement material 100 formed to be spaced apart from each other, circuit layers 201 and 202 formed on the insulation layer 1000, and a via 203 electrically connected to the circuit layers 201 and 202.

Here, the reinforcement material 100 may be glass cloth.

The insulation layer 1000 may have a structure in which the reinforcement material 100 is impregnated in a resin 101.

Here, the resin 101 may be a thermosetting resin such as an epoxy resin or a thermoplastic resin such as polyimide. Alternatively, the thermosetting resin, a photocurable resin, and the like may be used. According to the embodiment of the present invention, the insulating layer 1000 formed of the insulation material 1100 of FIG. 1.

The circuit layers 201 and 202 may be made of any conductive metal for a circuit without limit and be typically made of copper in the printed circuit board.

A surface treatment layer (not shown) may be further formed on an exposed circuit layer, if necessary.

The surface treatment layer may be formed by electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like, for example. The method of forming the surface treatment layer is not particularly limited thereto as long as it is known in the art.

The via region 200 may have a diameter larger than that of the via 203.

Accordingly, a side part of the formed via 203 and the reinforcement 100 may be spaced apart from each other.

The via 203 may have a sandglass shape.

FIG. 4 is a cross-sectional view showing a build-up layer.

As shown in FIG. 4, the printed circuit board 3000 may include an insulation layer 1000 having the via region 200 and the reinforcement material 100 formed to be spaced apart from each other, circuit layers 201 and 202 formed on the insulation layer 1000, and a via 203 electrically connected to the circuit layers 201 and 202.

Here, the reinforcement material 100 may be glass cloth.

The insulation layer 1000 may have a structure in which the reinforcement material 100 is impregnated in a resin 101. According to the embodiment of the present invention, the insulating layer 1000 formed of the insulation material 1100 of FIG. 1.

Here, the resin 101 may be a thermosetting resin such as an epoxy resin or thermoplastic resin such as polyimide. Alternatively, the thermosetting resin, a photocurable resin, and the like may be used.

The circuit layers 201 and 202 may be made of any conductive metal for a circuit without limit and be typically made of copper in the printed circuit board.

A surface treatment layer (not shown) may be further formed on an exposed circuit layer, if necessary.

The surface treatment layer may be formed by electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like, for example. The method of forming the surface treatment layer is not particularly limited thereto as long as it is known in the art.

The via region 200 may have a diameter larger than that of the via 203.

Accordingly, a side part of the formed via 203 and the reinforcement material 100 may be spaced apart from each other.

A shape of the via 203 may be a taper shape in which the diameter of the via 203 becomes smaller toward a lower end portion thereof.

### Method of Manufacturing Printed Circuit Board

FIGS. 5 through 7 are process flow charts of a method of manufacturing a printed circuit board according to still another exemplary embodiment of the present disclosure.

As shown in FIG. 5, a core substrate including an insulation layer 1000 having the via region 200 and the reinforcement material 100 formed to be spaced apart from each other is prepared.

The reinforcement material 100 may be glass cloth.

In addition, the insulation layer 1000 may have a structure in which the reinforcement material 100 is impregnated in a resin 101. According to the embodiment of the present invention, the insulating layer 1000 formed of the insulation material 1100 of FIG. 1.

Here, the resin 101 may be a thermosetting resin such as an epoxy resin or thermoplastic resin such as polyimide. Alternatively, the thermosetting resin, a photocurable resin, and the like may be used.

Here, the core substrate may be a copper clad laminate (CCL).

Although not shown, a copper foil 110 formed on an outer layer of the core substrate may be removed by an etching.

In addition, a via hole may be machined in the via region 200 by machining one surface of the core substrate and a via hole having a sandglass shape may be formed by re-machining the other surface of the core substrate.

In this case, the via hole may be formed using a mechanical drill or a laser drill. The laser drill may be a CO₂ laser drill or a YAG laser drill, but is not particularly limited thereto.

Although not shown, a seed layer may be formed by performing an electroless copper plating or sputtering method on an inner wall of the formed via hole, and a method of forming the seed layer is not particularly limited thereto.

In addition, although not shown, a plating resist having an opening part corresponding to a region in which a circuit is to be formed may be formed.

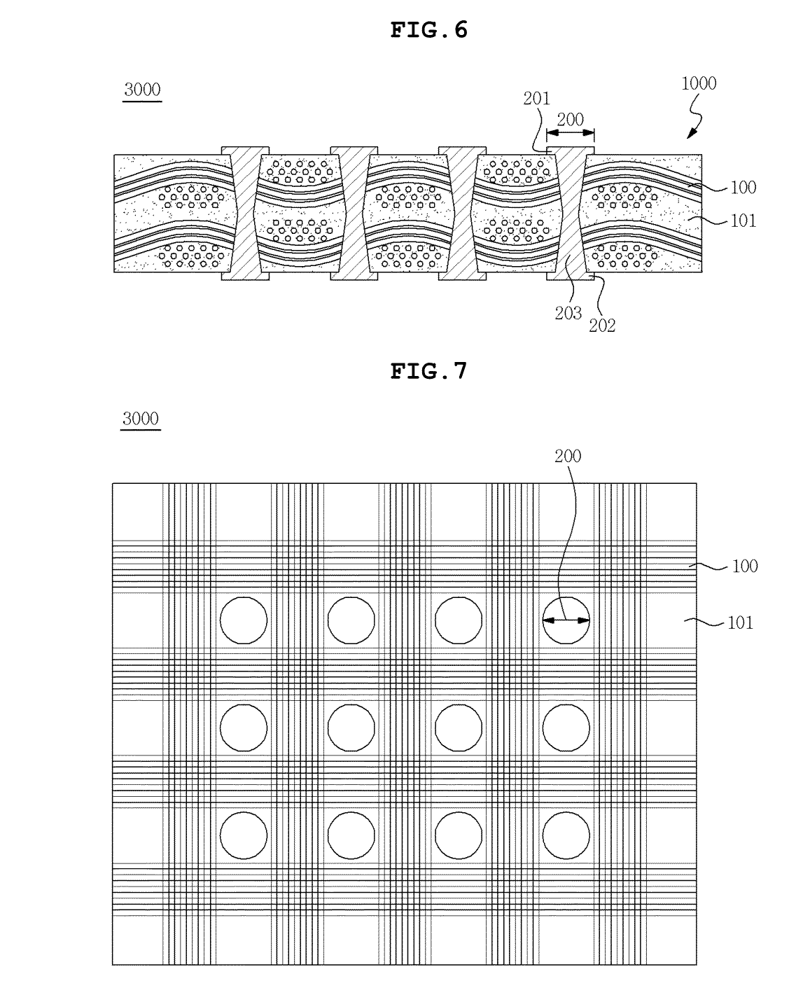

As shown in FIG. 6, the plating may be performed in the via and the opening part.

The via 203 and the circuit layers 201 and 202 may be formed by delaminating the plating resist and etching the seed layer.

As shown in FIG. 7, the via 203 formed in the via region 200 and the reinforcement material 100 may be formed to be spaced apart from each other.

According to the exemplary embodiments of the present disclosure, the insulation material, the printed circuit board using the same, and the method of manufacturing the same do not have the glass cloth in the via region, thereby making it possible to increase the reliability upon machining the via hole using the laser drill.

In addition, since the glass cloth is not within the via, the plating solution is freely circulated, thereby making it possible to improve the void defect.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure. Although the embodiment of the present disclosure has been disclosed that the via has a sandglass or taper shape, it will be appreciated that the present disclosure is not limited thereto. That is, even though it is not shown in FIGS. 1 to 7, the via may be formed in a cylinder shape.

Accordingly, any and all modifications, variations or equivalent arrangements should be considered to be within the scope of the disclosure, and the detailed scope of the disclosure will be disclosed by the accompanying claims.

What is claimed is:

1. An insulation material comprising:
a via region in which a via is to be formed; and
a reinforcement material,
wherein the via region and the reinforcement material are formed to be spaced apart from each other.

2. The insulation material of claim 1, wherein the reinforcement material is glass cloth.

3. A printed circuit board comprising:
an insulation layer having a via region and a reinforcement material formed to be spaced apart from each other;
circuit layers formed on the insulation layer; and
a via electrically connected to the circuit layers.

4. The printed circuit board of claim 3, wherein the reinforcement material is glass cloth.

5. The printed circuit board of claim 3, wherein the via region has a diameter larger than that of the via.

6. The printed circuit board of claim 3, wherein the via has a sandglass, taper shape or cylinder shape.

7. A method of manufacturing a printed circuit board, the method comprising:
preparing a core substrate including an insulation layer having a via region and a reinforcement material formed to be spaced apart from each other; and
forming a via within the via region to penetrate through the insulation layer in the core substrate.

8. The method of claim 7, wherein the reinforcement material is glass cloth.

9. The method of claim 7, wherein the via region has a diameter larger than that of the via.

10. The method of claim 7, wherein the via has a sandglass, taper shape or cylinder shape.
